(19) United States
(12) Patent Application Publication
(10) Pub. No.: US 2015/0268682 A1
(43) Pub. Date: Sep. 24, 2015

(54) SYSTEMS AND METHODS FOR MANAGING POWER SUPPLY SYSTEMS

(71) Applicant: Elwha LLC, Bellevue, WA (US)

(72) Inventors: Roderick A. Hyde, Redmond, WA (US); Clarence T. Tegreene, Bellevue, WA (US); Joshua C. Walter, Kirkland, WA (US)

(21) Appl. No.: 14/223,574

(22) Filed: Mar. 24, 2014

(51) Int. Cl. G05F 1/66; H05K 7/20; G05B 15/02

(52) U.S. Cl. CPC G05F 1/66; G05B 15/02; H05K 7/20

(57) ABSTRACT

A power supply system includes a fuel cell configured to be activated from an inactive state to an active state to provide electricity to a power consuming system; and a heat transfer device configured to transfer heat energy generated by the power consuming system to the fuel cell while the fuel cell is in the inactive state.

### BACKGROUND

A power consuming system may utilize one or more secondary power supply systems to provide electricity to the power consuming system should a primary power supply system become unavailable or otherwise unable to satisfy the power requirements of the power consuming system. For example, a data center may include a number of servers and other computing devices and utilize a power grid (e.g., a municipal power supply provided by a power plant) as a primary power source. The data center may also utilize diesel generators and/or batteries as secondary power supplies should the supply of electricity from the power grid become unavailable or otherwise insufficient to satisfy the power demands of the data center.

### SUMMARY

One embodiment relates to a power supply system including a fuel cell configured to be activated from an inactive state to an active state to provide electricity to a power consuming system in the active state; and a heat transfer device configured to transfer heat energy generated by the power consuming system to the fuel cell while the fuel cell is in the inactive state.

Another embodiment relates to a power supply system including a primary power system configured to provide electricity to a power consuming system; a secondary power system configured to be activated from an inactive state to an active state to provide electricity to the power consuming system in the active state; a heat transfer device configured to transfer heat energy generated by the power consuming system to the secondary power system while the secondary power system is in the inactive state; and a controller configured to control operation of the heat transfer device.

Another embodiment relates to a method of managing a power supply system, the method including providing electricity from a primary power system to a power consuming system; acquiring temperature data regarding a fuel cell, the fuel cell configured to be activated from an inactive state to an active state to provide electricity to the power consuming system in the active state; and providing heat energy generated by the power consuming system to the fuel cell while the fuel cell is in the inactive state.

Another embodiment relates to a method of managing a power supply system, the method including maintaining a fuel cell in an inactive state such that the fuel cell produces substantially no electricity while in the inactive state, the fuel cell configured to be activated to produce electricity for a power consuming system; and maintaining a temperature of the fuel cell at or above a target temperature while the fuel cell is in the inactive state by directing heat energy generated by the power consuming system to the fuel cell.

Another embodiment relates to a system including a data center configured to provide data storage capabilities; a primary power source configured to satisfy a power demand of the data center; a fuel cell configured to be activated from an inactive state to an active state based on the primary power source being unable to satisfy the power demand of the data center; a heat transfer device configured to transfer heat energy generated by the data center to the fuel cell at least while the fuel cell is in the inactive state; and a controller configured to control operation of the heat transfer device.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic representation of a power management system according to one embodiment.

FIG. 2 is a schematic representation of the power management system of FIG. 1 shown in greater detail according to one embodiment.

FIG. 3 is a schematic representation of a fuel cell according to one embodiment.

FIG. 4 is a schematic representation of a power management system according to another embodiment.

FIG. 5 is a schematic representation of a control system for the power management system of FIG. 1 according to one embodiment.

FIG. 6 is a schematic representation of a fuel cell assembly according to another embodiment.

FIG. 7 is a block diagram illustrating a method of managing a power supply system according to one embodiment.

### DETAILED DESCRIPTION

In the following detailed description, reference is made to the accompanying drawings, which form a part thereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here.

Referring to the figures generally, various embodiments disclosed herein relate to secondary power systems or sources such as fuel cells, and more specifically, to using a fuel cell as a secondary power system for a power consuming system. Generally, a power consuming system (e.g., data center, hospital, public facility) receives electricity from a primary power system, such as the electrical grid. However, at times, the primary power system may become unavailable (e.g., due to power plant operation interruptions or power transmission failures) or otherwise unable to satisfy the power demands of the power consuming system. In order to continue to satisfy the power demands of the power consuming system, one or more backup, or secondary power systems, such as a fuel cell, may be utilized. However, fuel cells often provide optimal or maximum power generation capabilities only at elevated temperatures (e.g., at temperatures elevated relative to ambient temperatures). As such, various embodiments disclosed herein relate to maintaining a fuel cell at or above an elevated target temperature prior to use of the fuel cell (e.g., prior to using the fuel cell to provide electricity to a power consuming system). Waste heat generated by a power consuming system can be utilized to provide the primary heat energy required to maintain the fuel cell at or above the target temperature.

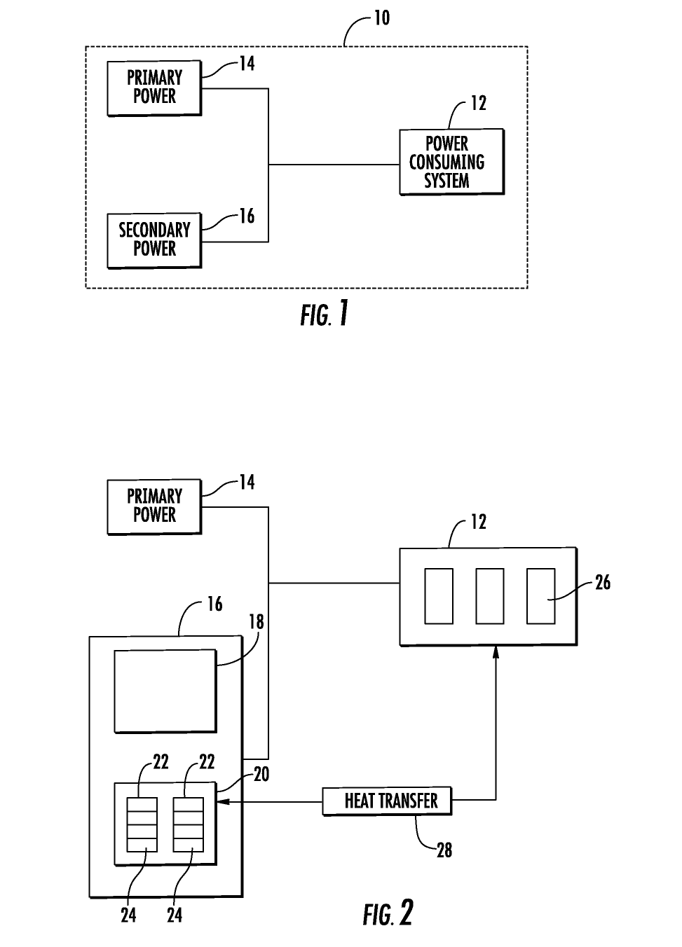

Referring now to FIG. 1, power management system 10 is shown according to one embodiment, and includes power consuming system 12, primary power system 14, and secondary power system 16. System 10 is configured such that during normal operation, power consuming system 12 receives electricity from primary power system 14. During periods of time when primary power system 14 is not able to satisfy the power demands of power consuming system 12, power consuming system 12 receives electricity from secondary power system 16 (e.g., rather than or in addition to receiving electricity from primary power system 14). System 10 is usable in connection with a variety of applications, including data centers, hospitals, public facilities, power plants such as nuclear power plants, and the like.

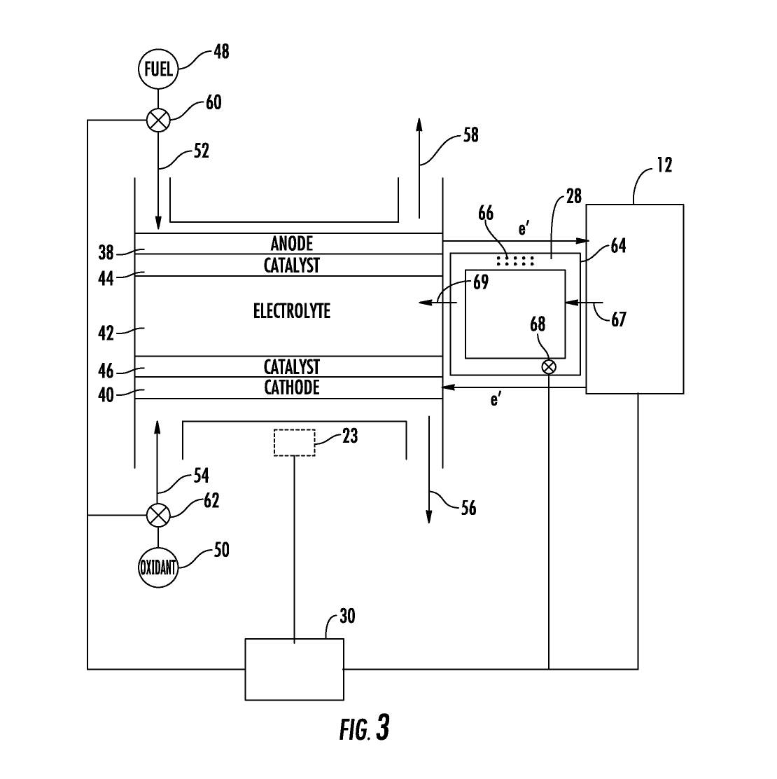

Referring to FIG. 2, power management system 10 is shown in greater detail according to one embodiment. As shown in FIG. 2, primary power system 14 and secondary power system 16 are configured to provide electricity to power consuming system 12. Power consuming system 12 includes a number of power consuming devices 26. Secondary power system 16 includes a fuel cell 20. Fuel cell 20 in turn includes one or more fuel cell stacks 22 made up of unit cells 24. In one embodiment, secondary power system 16 includes only fuel cell 20. In other embodiments, in addition to fuel cell 20, secondary power system 16 includes additional redundant power systems 18, such as generators, battery systems, and the like. Power consuming system 12 generates waste or heat energy (e.g., by way of operation of one or more computing devices in the case of a data center). A portion of the waste or heat energy generated by power consuming system 12 is transferred to fuel cell 20 by way of heat transfer device 28.

In one embodiment, power consuming system 12 can be a data center configured to provide computer processing functionality, telecommunications functionality, data storage functionality, or other functionality, and power consuming devices 26 can include one or more servers, processors, data storage devices, etc. Alternatively, power consuming system 12 can be a hospital (e.g., including various computing and/or medical device systems), public facility (e.g., an airport, train station, etc.), or other power consuming system.

Referring now to FIG. 3, fuel cell 20 is shown in greater detail according to one embodiment. Fuel cell 20 includes anode 38, cathode 40, and electrolyte 42. According to the embodiment shown in FIG. 3, fuel cell 20 further includes catalysts 44, 46. Electrolyte 42 may be a liquid phosphoric acid ceramic in a lithium oxide matrix, a solid oxide, an alkali carbonate retained in a ceramic matrix of lithium hydroxide, a solid ceramic, a solid polymer membrane, a potassium hydroxide solution in water, or another electrolyte.

Referring further to FIG. 3, during operation, fuel cell 20 produces electricity from reactants (e.g., fuel, oxidants). Fuel cell 20 receives a fuel (e.g., hydrogen, a hydrocarbon, an alcohol, etc.) from fuel supply 48 by way of fuel flow path 52. Fuel cell 20 receives an oxidant (e.g., oxygen, air, etc.) from oxidant supply 50 by way of oxidant flow path 54. Fuel from fuel source 48 interacts with anode 38, and the oxidant from oxidant source 50 interacts with cathode 40. At anode 38, positively charged ions (e.g., hydrogen ions) and negatively charged electrons are produced. Excess fuel flows from fuel cell 20 along flow path 58. Only the positively charged ions pass through electrolyte 42 to cathode 40. The negatively charged electrons flow along an external circuit to provide electricity to power consuming system 12.

The negatively charged electrons produce an electrical current. In one embodiment, the electrical current is a direct current. A DC/DC booster may be disposed between fuel cell 20 and power consuming system 12 to increase the voltage of the direct current. In other embodiments, an inverter is disposed between fuel cell 20 and power consuming system 12 to convert the direct current into alternating current. At cathode 40, the negatively charged electrons and the positively charged ions combine with oxygen from the oxidant to produce product (e.g., water), which flows out of fuel cell 20 along flow path 56. Excess oxidant from oxidant source 50 flows out from fuel cell 20 along flow path 56. It should be noted that according to various alternative embodiments, other configurations of fuel cell 20 can be utilized. Furthermore, while FIG. 3 depicts fuel cell 20 as including a single anode, cathode, and catalyst, as noted above, fuel cell 20 can be made up of any number of individual unit cells and/or cell stacks, with each unit cell including an anode, cathode, electrolyte, etc.

The electricity or power generation of fuel cell 20 can vary based on, for example, the type of fuel cell, the size of the fuel cell stacks used, and other factors. In one embodiment, the output of fuel cell 20 can be less than 1 KW, between 1 and 10 KW, between 10 and 100 KW, between 100 KW and 1 MW, or greater than 1 MW. Individual fuel cell stacks can provide known levels of output, such as 100 KW per stack, 500 KW per stack, and so on.

In one embodiment, valves 60, 62 control the supply of fuel and oxidants to fuel cell 20. By controlling the flow of fuel and oxidants, the production of electricity by fuel cell 20 can be controlled. As shown in FIG. 3, controller 30 is coupled to valves 60, 62 such that controller 30 can control the operation of valves 60, 62 based on a variety of factors, including the power demands of power consuming system 12 and whether primary power system 14 can meet such power demands. For example, while power consuming system 12 receives sufficient electricity from primary power system 14, controller 30 can control valves 60, 62 such that substantially no fuel or oxidants flow to fuel cell 20, and therefore substantially no electricity is produced.

Should primary power system 14 become unavailable or otherwise unable to satisfy the power demands of power consuming system 12, controller 30 can actuate valves 60, 62 such that fuel and oxidants flow to fuel cell 20, and fuel cell 20 produces electricity for use by power consuming system 12. As discussed in greater detail below, based on the power demands of power consuming system 12, controller 30 can control the amount of fuel and oxidants provided to fuel cell 20 accordingly (i.e., by control of valves 60, 62).

In some embodiments, an operational temperature of fuel cell 20 (e.g., a temperature at which fuel cell 20 produces electricity at a desired, maximum, or optimal rate) is elevated relative to ambient temperature conditions surrounding fuel cell 20. As such, in order to maintain fuel cell 20 at or near the operational temperature of fuel cell 20 (e.g., at a target temperature), heat energy is provided to fuel cell 20 prior to use of fuel cell to provide electricity to power consuming system 12. For example, fuel cell 20 may be maintained at or above an elevated target temperature while in a standby state (e.g., in an inactive, disengaged, non-operating, or non-electricity-producing state, while power consuming system 12 receives power from primary power system 14). As such, should primary power system 14 become unavailable or otherwise unable to satisfy the power demands of power consuming system 12, fuel cell 20 can be activated (e.g., by providing reactants to fuel cell 20) while at or above the target temperature, such that little or no warm up time is required for fuel cell 20 to produce electricity at a desired rate.

In one embodiment, temperature sensor 23 is configured to acquire temperature data regarding fuel cell 20 (e.g., a current temperature of fuel cell 20). Sensor 23 communicates the temperature data to controller 30. Based on the temperature data, controller 30 can control operation of heat transfer device 28 accordingly (e.g., to transfer more or less heat energy generated by power consuming system 12 to fuel cell 20).

As shown in FIG. 3, in one embodiment, heat transfer device 28 includes heat transfer member 64 (e.g., a heat exchanger, heat pump, heat pipe, pipe, conduit, etc.) through which a heat transfer fluid 66 (e.g., a gas, liquid, etc.) flows (e.g., in a closed loop fashion). A heat transfer control member 68 controls the flow of fluid 66 through heat transfer member 64. Control member 68 can include one or more valves, pumps, etc. usable to control the flow rate of fluid 66 through heat transfer member 64. While fluid 66 is flowing, heat energy generated by power consuming system 12 is absorbed by fluid 66 and transferred to fuel cell 20 (e.g., as shown by heat energy flow paths 67, 69). In some embodiments, heat transfer device 28 can be configured such that while fluid 66 is not flowing, power consuming system 12 is substantially thermally insulated from fuel cell 20.

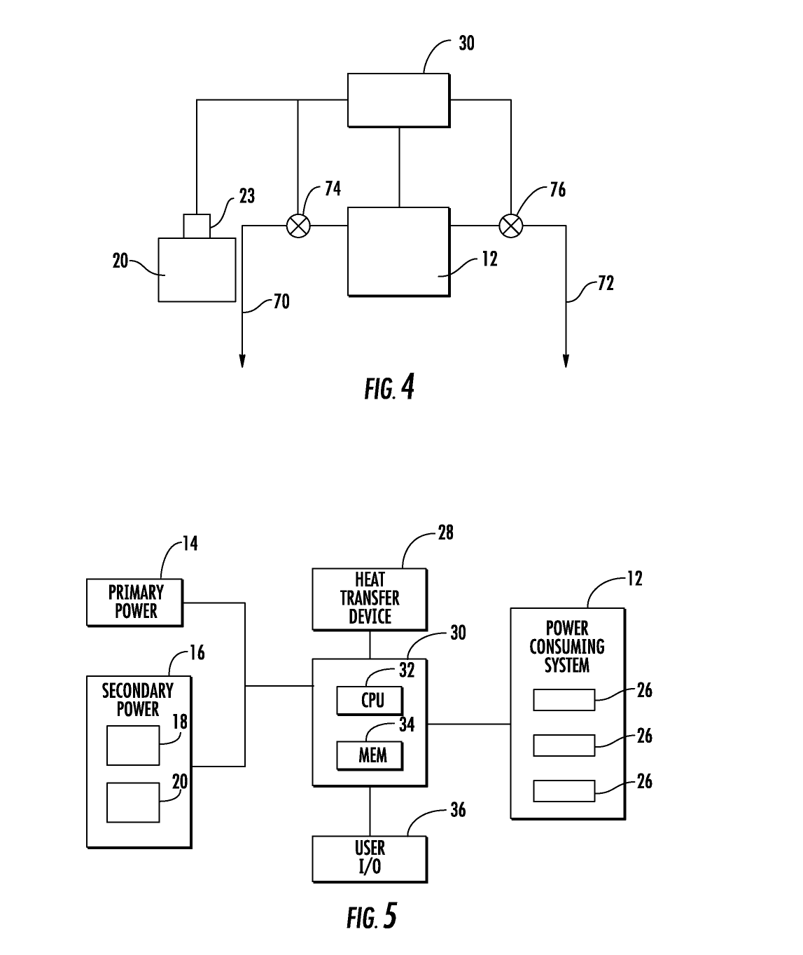

In an alternative embodiment, heat transfer device 28 can be provided in the form of an exhaust or cooling system for a power consuming system. For example, referring to FIG. 4, power consuming system 12 can be fluidly coupled to first and second exhaust conduits 70, 72. First and second conduits 70, 72 are configured to direct a fluid from power consuming system 12 to an exterior environment. In some embodiments, the fluid includes a liquid. In other embodiments, the fluid includes a gas. In one embodiment, first and second conduits 70, 72 direct heated air or other gases from an interior of a power consuming system to an exterior environment.

As shown in FIG. 4, first conduit 70 is configured to direct fluid past fuel cell 20 such that heat energy is transferred from the fluid within first conduit 70 to fuel cell 20. Second conduit 72 is configured such that fluid travelling through second conduit 72 is thermally insulated from fuel cell 20, and therefore heat energy is not transferred from the fluid within second conduit 72 to fuel cell 20. As such, by controlling the relative amounts of fluid travelling through first conduit 70 and second conduit 72, the amount of heat energy transferred to fuel cell 20 can be controlled accordingly.

In one embodiment, first exhaust control member 74 controls the flow of fluid through first conduit 70, and second exhaust control member 76 controls the flow of fluid through second conduit 72. Controller 30 is coupled to first and second exhaust control members 74, 76, and is configured to control operation of first and second exhaust control members 74, 76. Controller 30 can be configured to control operation of first and second exhaust control members 74, 76 to control the temperature of fuel cell 20 (e.g., to keep a temperature of fuel cell 20 at or above a target temperature, to keep the temperature of fuel cell 20 within a desired temperature range, etc.).

A target temperature or target temperature range for fuel cell 20 can be determined based on any of the factors discussed herein. In some embodiments, the target temperature is approximately 50 degrees Celsius (C), approximately 80 degrees C., or approximately 100 degrees C. In alternative embodiments, higher or lower target temperatures can be utilized, such as 150 degrees C., 200 degrees C., or higher. In some embodiments, it is desirable to maintain the fuel cell temperature below a specified threshold temperature (e.g., to prevent damage to the fuel cell, or to optimize performance). In further embodiments, the target temperature includes a temperature range (i.e., greater than the target temperature and less than a relatively higher threshold temperature), such as 50-100 degrees C., 150-200 degrees C., etc. In yet further embodiments, the target temperature is a minimum temperature.

Referring further to FIGS. 3-4, according to various alternative embodiments, heat transfer device 28 can be configured to transfer heat energy generated by power consuming system 12 to various components of fuel cell 20. For example, in one embodiment, heat transfer device 28 is configured to transfer heat energy to an exterior housing or portion of fuel cell 20. In other embodiments, heat transfer device 28 is configured to transfer heat energy to one or more interior components of fuel cell 20, including an anode, cathode, or electrolyte. In further embodiments, heat transfer device 28 is configured to transfer heat energy to one or more reactants (e.g., a fuel and/or an oxidant) used by fuel cell 20.

Referring to FIG. 5, controller 30 usable to communicate with and/or control various components of power management system 10 is shown in greater detail according to one embodiment. As shown in FIG. 5, controller 30 includes processor 32 and memory 34. Processor 32 may be implemented as a general-purpose processor, an application specific integrated circuit (ASIC), one or more field programmable gate arrays (FPGAs), a digital-signal-processor (DSP), a group of processing components, or other suitable electronic processing components. Memory 34 is one or more devices (e.g., RAM, ROM, Flash Memory, hard disk storage, etc.) for storing data and/or computer code for facilitating the various processes described herein. Memory 34 may be or include non-transient volatile memory or non-volatile memory. Memory 34 may include database components, object code components, script components, or any other type of information structure for supporting the various activities and information structures described herein. Memory 34 may be communicably connected to processor 32 and provide computer code or instructions to processor 32 for executing the processes described herein.

Controller 30 is configured to communicate with (e.g., receive data from and/or transmit data to) power consuming system 12, primary power system 14, secondary power system 16, and heat transfer device 28. Controller 30 is further configured to receive various inputs from users and provide various outputs to users via input/output device 36. Controller 30 can receive temperature data (e.g., from sensor 23) regarding a current temperature of fuel cell 20, and based on the temperature data, control operation of heat transfer device 28 to increase or decrease the temperature of fuel cell 20. Temperature data regarding fuel cell 20 is acquired from sensor 23, and heat transfer device 28 can be controlled by actuation of control member 68 (or, in a similar manner, control members 74, 76).

A target temperature for fuel cell 20 (e.g., while fuel cell 20 is inactive) can be based on a variety of factors, including a maximum electricity production rate (e.g., the temperature at which electricity production for fuel cell 20 is maximized), a maximum efficiency level (a temperature at which electricity production for fuel cell 20 is most efficient in terms of fuel usage), the power requirements of power consuming system 12 (e.g., a temperature at which fuel cell 20 can satisfy current power requirements of power consuming system 12), an acceptable response time (e.g., a time period after activation of fuel cell during which the temperature of fuel cell 20 increases to a target temperature), and so on. According to further embodiments, a user can manually input desired temperature parameters for fuel cell 20 (e.g., by way of input/output device 36). In one embodiment, the efficiency of the fuel cell is based on a ratio of the amount of electrical energy output by the fuel cell relative to the calorific value of the fuel input to the fuel cell.

In some embodiments, controller 30 is further configured to monitor the “readiness” (e.g., the current production capacity) of fuel cell 20. For example, based on the current temperature of fuel cell 20, controller 30 can determine the maximum power demand that fuel cell 20 can satisfy, along with the amount of time until fuel cell 20 comes up to a target temperature. Based on the current temperature of fuel cell 20 and the power requirements of power consuming system 12, controller 30 can identify potential deficiencies in power supply levels and, as required, utilize additional power systems (e.g., power systems 18 shown in FIG. 3). Controller 30 can monitor and communicate data regarding the current states of power consuming system 12, primary power system 14, and secondary power system 16 to various users and other systems. For example, controller 30 can communicate data regarding a current state of fuel cell 20 to power consuming system 12. Based on the data, power consuming system 12 can reduce its power requirements based on detecting, for example, a potential deficiency in available power from fuel cell 20.

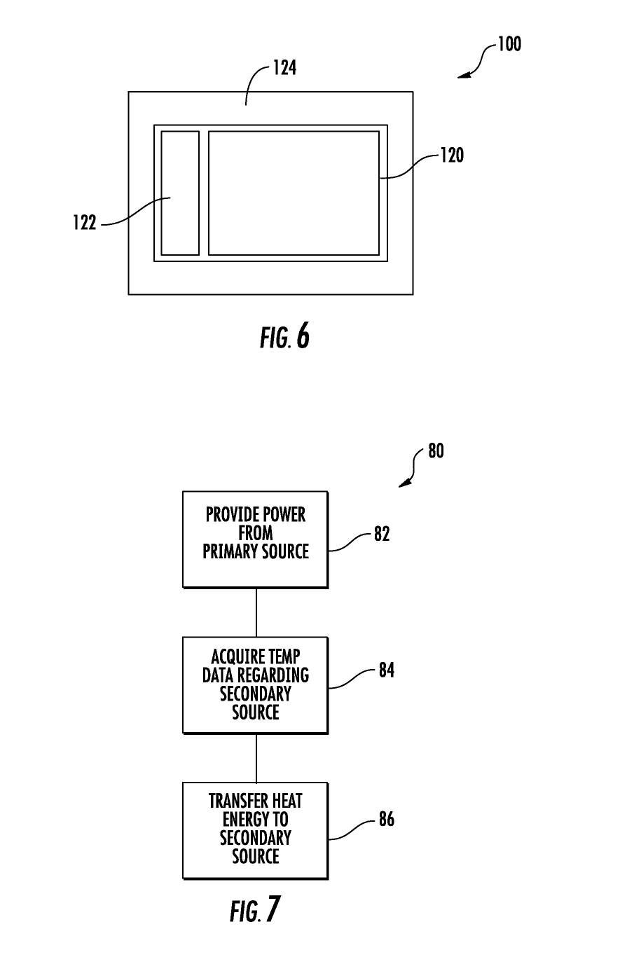

Referring now to FIG. 6, fuel cell assembly 100 is shown according to another embodiment. Fuel cell assembly 100 includes fuel cell 120, supplemental heating system 122, and insulation system 124. Fuel cell 120 is similar in construction and function to fuel cell 20, such that fuel cell 120 acts as a backup or secondary power system to a primary power system and provides electricity to a power consuming system in cases where the primary power system cannot meet the power demands of the power consuming system. Fuel cell 120 is configured to receive waste or heat energy from the power consuming system. In certain situations, the waste or heat energy generated by the power consuming system is insufficient to maintain fuel cell 120 at or above a desired target temperature. As such, a supplemental heating system, such as supplemental heating system 122, is in some embodiments configured to provide additional heat energy (e.g., second heat energy) to fuel cell 120.

Supplemental heating system 122 can be controlled by a controller such as controller 30. In one embodiment, controller 30 is configured to control operation of supplemental heating system 122 based on a current temperature of fuel cell 120 and the current heat energy being supplied to fuel cell 120 (e.g., from a power consuming system, etc.), such that any deficiencies of heat energy being provided to fuel cell 120 can be accommodated by supplemental heating system 122. In one embodiment, supplemental heating system 122 includes an electric heater. The electric heater can be powered by a primary power system such as primary power system 14. In other embodiments, supplemental heating system 122 can include different types of heaters and be powered by alternative power systems.

In some embodiments, fuel cell assembly 100 includes insulation system 124. Insulation system 124 is configured to thermally insulate fuel cell 120 from the surrounding environment such that the transfer of heat energy from fuel cell 120 to the environment is minimized. By reducing the heat energy loss from fuel cell 120, the heat energy required to be provided to fuel cell 120 to maintain fuel call 120 at an elevated temperature can likewise be reduced. Insulation system 124 can in some embodiments include a layer of insulating material surrounding all or a portion of fuel cell 120. Insulation system 124 can further include a layer of insulating material surrounding all or a portion of supplemental heating system 122.

Referring now to FIG. 7, method 80 of managing a power supply system is shown according to one embodiment. A primary power system provides electricity to a power consuming device (82). As noted above, in some embodiments, a municipal or other power grid provides power to a data center or other power consuming system. Temperature data is received regarding a secondary power system (84). In one embodiment, a sensor acquires temperature data regarding a fuel cell that acts as a secondary power system and is in an inactive state while the power consuming system receives power from the primary power system. Based on the temperature data, waste or heat energy generated by the power consuming system is transferred to the secondary power system (86). For example, a heat transfer device or exhaust system can be configured to selectively direct a heated fluid past portions of a fuel cell such that heat energy is transferred from the fluid to the fuel cell.

The present disclosure contemplates methods, systems, and program products on any machine-readable media for accomplishing various operations. The embodiments of the present disclosure may be implemented using existing computer processors, or by a special purpose computer processor for an appropriate system, incorporated for this or another purpose, or by a hardwired system. Embodiments within the scope of the present disclosure include program products comprising machine-readable media for carrying or having machine-executable instructions or data structures stored thereon. Such machine-readable media can be any available media that can be accessed by a general purpose or special purpose computer or other machine with a processor. By way of example, such machine-readable media can comprise RAM, ROM, EPROM, EEPROM, CD-ROM or other optical disk storage, magnetic disk storage or other magnetic storage devices, or any other medium which can be used to carry or store desired program code in the form of machine-executable instructions or data structures and which can be accessed by a general purpose or special purpose computer or other machine with a processor. When information is transferred or provided over a network or another communications connection (either hardwired, wireless, or a combination of hardwired or wireless) to a machine, the machine properly views the connection as a machine-readable medium. Thus, any such connection is properly termed a machine-readable medium. Combinations of the above are also included within the scope of machine-readable media. Machine-executable instructions include, for example, instructions and data which cause a general purpose computer, special purpose computer, or special purpose processing machines to perform a certain function or group of functions.

Although the figures may show a specific order of method steps, the order of the steps may differ from what is depicted. Also two or more steps may be performed concurrently or with partial concurrence. Such variation will depend on the software and hardware systems chosen and on designer choice. All such variations are within the scope of the disclosure. Likewise, software implementations could be accomplished with standard programming techniques with rule based logic and other logic to accomplish the various connection steps, processing steps, comparison steps and decision steps.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

1. A power supply system, comprising:
a fuel cell configured to be activated from an inactive state to an active state to provide electricity to a power consuming system in the active state; and
a heat transfer device configured to transfer heat energy generated by the power consuming system to the fuel cell while the fuel cell is in the inactive state.

2. The system of claim 1, wherein the heat transfer device is further configured to transfer heat energy generated by the power consuming system to the fuel cell while the fuel cell is in the active state.

3. The system of claim 1, further comprising a controller configured to control operation of the heat transfer device.

4. The system of claim 3, wherein the controller is configured to control operation of the heat transfer device to maintain the fuel cell at or above a target temperature.

5. The system of claim 4, wherein the controller is further configured to control operation of the heat transfer device to maintain the fuel cell at or below a threshold temperature, wherein the threshold temperature is greater than the target temperature.

6-19. (canceled)

20. The system of claim 1, wherein the heat transfer device is configured to provide the heat energy to a reactant used by the fuel cell to produce electricity.

21-22. (canceled)

23. The system of claim 1, wherein the heat transfer device includes a heat exchanger.

24. The system of claim 23, wherein the heat exchanger is configured to circulate a fluid, wherein the fluid receives heat energy generated by the power consuming system and provides the heat energy to the fuel cell.

25. The system of claim 24, wherein the fluid includes a gas.

26. The system of claim 24, wherein the fluid includes a liquid.

27-35. (canceled)

36. The system of claim 1, wherein the heat energy is first heat energy, further comprising a supplemental heating device configured to provide second heat energy to the fuel cell.

37. The system of claim 36, further comprising a controller configured to control operation of the supplemental heating device based on a temperature of the fuel cell and an amount of the first heat energy.

38-41. (canceled)

42. A power supply system, comprising:
a primary power system configured to provide electricity to a power consuming system;
a secondary power system configured to be activated from an inactive state to an active state to provide electricity to the power consuming system in the active state;
a heat transfer device configured to transfer heat energy generated by the power consuming system to the secondary power system while the secondary power system is in the inactive state; and
a controller configured to control operation of the heat transfer device.

43. The system of claim 42, wherein the heat transfer device is further configured to transfer heat energy generated by the power consuming system to the secondary power system while the secondary power system is in the active state.

44. The system of claim 42, wherein the controller is configured to control operation of the heat transfer device to maintain the secondary power system at or above a target temperature while the secondary power system is in the inactive state.

45. The system of claim 44, wherein the controller is further configured to control operation of the heat transfer device to maintain the fuel cell at or below a threshold temperature, wherein the threshold temperature is greater than the target temperature.

46. The system of claim 44, wherein the target temperature is higher than an ambient temperature of an environment of the secondary power system.

47-48. (canceled)

49. The system of claim 44, wherein the controller is configured to determine the target temperature based on an electricity output rate of the secondary power system.

50. (canceled)

51. The system of claim 44, wherein the controller is configured to determine the target temperature based on an efficiency of the secondary power system.

52. (canceled)

53. The system of claim 44, wherein the controller is configured to determine the target temperature based on a power demand of the power consuming system.

54. The system of claim 44, wherein the controller is configured to determine the target temperature based on a period of time during which an electricity production rate of the secondary power system increases to a target electricity production rate.

55-59. (canceled)

60. The system of claim 42, wherein the heat transfer device is configured to provide the heat energy to a reactant used by the secondary power system to produce electricity.

61. The system of claim 60, wherein the reactant includes a fuel.

62. The system of claim 60, wherein the reactant includes an oxidant.

63-158. (canceled)

159. A system, comprising:
a data center configured to provide data storage capabilities;
a primary power source configured to satisfy a power demand of the data center;
a fuel cell configured to be activated from an inactive state to an active state based on the primary power source being unable to satisfy the power demand of the data center;
a heat transfer device configured to transfer heat energy generated by the data center to the fuel cell at least while the fuel cell is in the inactive state; and
a controller configured to control operation of the heat transfer device.

160. The system of claim 159, wherein the controller is configured to control operation of the heat transfer device to maintain a temperature of the fuel cell at or above a target temperature.

161. The system of claim 160, wherein the target temperature is determined based on the power demand of the data center.

162. The system of claim 160, wherein the target temperature is determined based on an efficiency of the fuel cell.

163. The system of claim 160, wherein the target temperature is determined based on a period of time during which the fuel cell increases electricity production to a target production rate.

164. The system of claim 159, wherein the controller is configured to control operation of the heat transfer device to vary an amount of heat energy transferred to the fuel cell based on a temperature of the fuel cell.

165-167. (canceled)

168. The system of claim 159, wherein the heat transfer device includes an exhaust system configured to direct an exhaust fluid from the data center past at least a portion of the fuel cell.

169. The system of claim 168, wherein the exhaust fluid includes a gas.

170. The system of claim 168, wherein the exhaust fluid includes a liquid.

171. The system of claim 159, further comprising a thermal insulation system configured to thermally insulate the fuel cell.

172. The system of claim 159, further comprising a supplemental heating system configured to provide supplemental heat energy to the fuel cell to supplement the heat energy generated by the data center.
